(19) United States
(12) Patent Application Publication
(10) Pub. No.: US 2026/0343784 A1
(43) Pub. Date: Oct. 29, 2026

(54) Power Distribution System for Server Information Handling System Rack

(71) Applicant: Dell Products L.P., Round Rock, TX (US)

(72) Inventor: David L. Roper, Austin, TX (US)

(21) Appl. No.: 19/191,075

(22) Filed: Apr. 28, 2025

(51) Int. Cl. H05K 7/14

(52) U.S. Cl. CPC H05K 7/1492

(57) ABSTRACT

A power distribution system for an information handling system server rack. The power distribution system includes a power distribution device, the power distribution device extending across the information handling system server rack and a capacitance system associated with the power distribution device, the capacitance system being physically and electrically coupled to the power distribution device.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system server rack with a power distribution system.

In one embodiment, the invention relates to a power distribution system for an information handling system server rack, comprising: a power distribution device, the power distribution device extending across the information handling system server rack; and, a capacitance system associated with the power distribution device, the capacitance system being physically and electrically coupled to the power distribution device.

In another embodiment, the invention relates to an information handling system server rack comprising: a server rack panel; and, a power distribution system mounted to the server rack panel, the power distribution system comprising a power distribution device, the power distribution device extending across the information handling system server rack; and, a capacitance system associated with the power distribution device, the capacitance system being physically and electrically coupled to the power distribution device.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIGS. 3A, 3B and 3C, generally referred to as FIG. 3, show a rack front view, a rack side view, and a rack side view with an information handling system.

FIG. 4 shows a block diagram view of a server rack system with a power distribution system.

FIG. 5 shows a block diagram view of a server rack system with a power distribution system.

FIG. 6 shows a block diagram view of a server rack system with a power distribution system.

FIG. 7 shows a cross-sectional view of a power distribution system.

FIG. 8 shows a cross-sectional view of another power distribution system.

FIG. 9 shows a cross-sectional view of another power distribution system.

### DETAILED DESCRIPTION

Various aspects of the present disclosure include an appreciation that it is known to mount a plurality of information handling systems within a server rack. Various aspects of the present disclosure include an appreciation that it is known to provide power to the plurality of information handling systems via a power distribution system. Various aspects of the present disclosure include an appreciation that a power distribution system is configured as a busbar. Various aspects of the present disclosure include an appreciation that busbars are often configured as a metallic strip which provides power to the plurality of information handling systems. Various aspects of the present disclosure include an appreciation that busbars are often mounted to a rear of a server rack and extend vertically across the rear of the server rack.

Various aspects of the present disclosure include an appreciation that in certain IT configurations using racks with vertical power busbars, power demands can significantly vary during operation potentially resulting in undesirable voltage drops and power surges along the vertical busbar. Various aspects of the present disclosure include an appreciation that these voltage drops and power surges can be mitigated by adding capacitance to individual system components or by adding a separate capacitive shelf to the rack. Various aspects of the present disclosure include an appreciation that adding capacitance to individual components can require use of additional internal space in typically already crowded layouts. Various aspects of the present disclosure include an appreciation that adding a separate capacitive shelf to the rack can require use of additional rack space in typically already crowded rack layouts.

Various aspects of the present disclosure include an appreciation that it would be desirable to provide a means of adding a capacitance function to server racks which does not require additional system internal space or additional rack space.

A system and method are disclosed for providing a power distribution system. In certain embodiments, the power distribution system includes an associated capacitance system to a server rack. In certain embodiments, the power distribution system includes a busbar associated capacitance system.

In certain embodiments, the busbar distributed capacitance system is incorporated within the server rack by directly mounting a capacitance system to the busbar, by providing a capacitance system which includes a plurality of capacitive modules mounted to the busbar, by incorporating capacitive features into the busbar housing design (e.g., via conductive parallel plates separated by a dielectric material/filler), or a combination thereof.

Such a power distribution system advantageously adds a capacitance function to server racks which does not require additional system internal space or additional rack space. More specifically, associating a capacitance system with a busbar can avoid the need to accommodate additional components within an IT system chassis and can also avoid any slot penalty associated with adding a separate capacitive shelf.

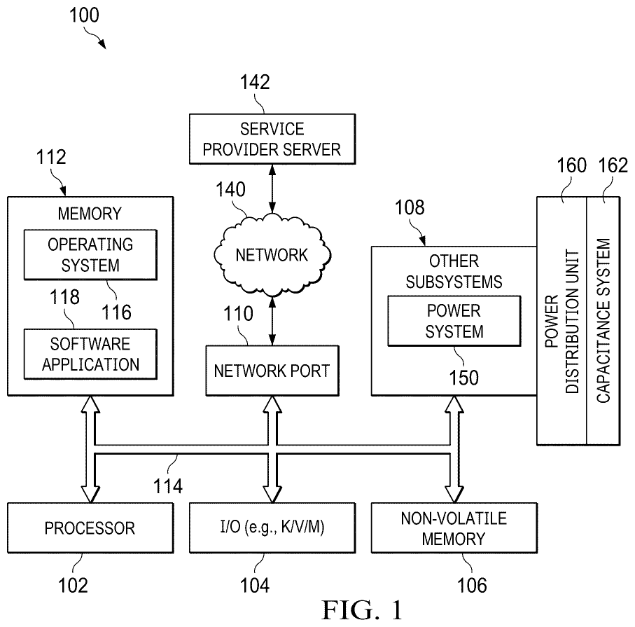

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the information handling system 100 includes a power system 150. In certain embodiments, the power system 150 of the information handling system is coupled to a power distribution system 160. In certain embodiments, the power distribution system 160 includes an associated capacitance system 162. In certain embodiments, the power system 150 includes one or more power supplies. In certain embodiments, the one or more power supplies power various components of the information handling system 100.

In certain embodiments, the power distribution system 160 is configured to be installed to a server rack. In certain embodiments, the power distribution system 160 includes one or more busbars. In certain embodiments, the capacitance system 162 includes a busbar associated capacitance system.

In certain embodiments, the busbar distributed capacitance system is incorporated within the server rack by directly mounting a capacitance system to the busbar, by providing a capacitance system which includes a plurality of capacitive modules mounted to the busbar, by incorporating capacitive features into the busbar housing design (e.g., via conductive parallel plates separated by a dielectric material/filler), or a combination thereof.

Such a power distribution system advantageously adds a capacitance function to server racks which does not require additional system internal space or additional rack space. More specifically, associating a capacitance system with a busbar can avoid the need to accommodate additional components within an IT system chassis and can also avoid any slot penalty associated with adding a separate capacitive shelf.

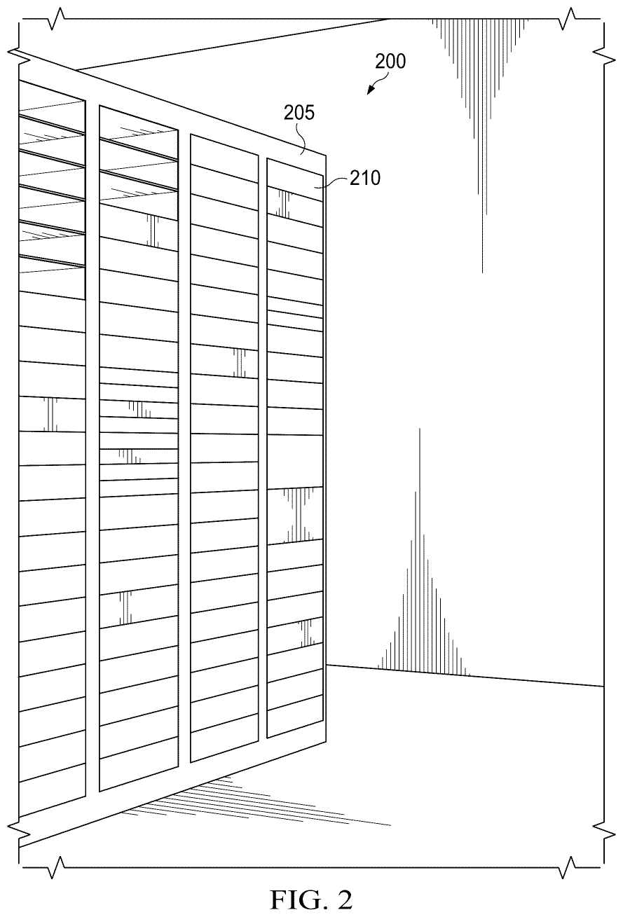

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high. In certain embodiments, the plurality of service sizes includes open rack (OU) server sizes. As used herein, an open rack server size broadly refers to a standardized server system height conforming to an OpenRack standard.

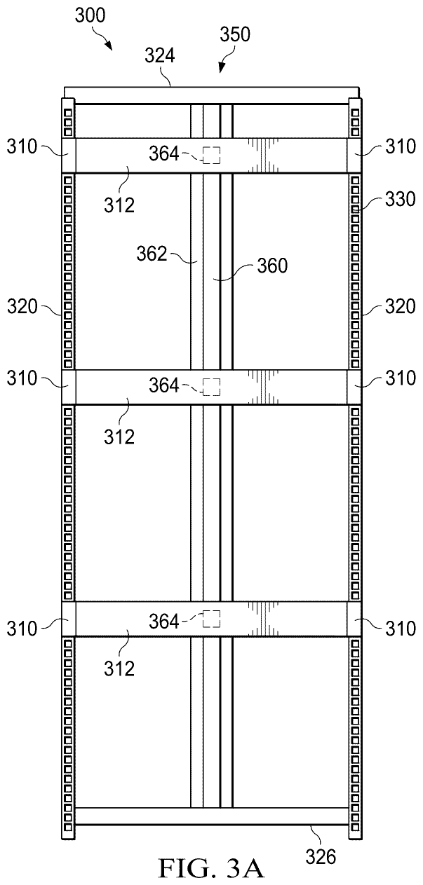

FIGS. 3A, 3B and 3C show a rack front view, a rack side view, and a rack rear view of a rack system 300 in which information handling systems 305 may be mounted. For illustration purposes, the information handling systems 305 are only shown in FIGS. 3B and 3C. In certain embodiments, the information handling systems 305 include server type information handling systems, a power shelf, or a combination thereof.

In certain embodiments, the rack system 300 includes a first front side panel 320, a second front side panel 320, a first rear side panel 322, a second rear side panel 322, or a combination thereof. In certain embodiments, the rack further includes a top panel 324, a bottom panel 326, or a combination thereof. A first server mounting component 310 is attached to one side of the rack and a second server mounting component 310 is attached to another side of the rack 300. In certain embodiments, the first server mounting component is attached to a first front side panel 320 and a first rear side panel 322 of the rack 300. In certain embodiments, the second server mounting component is attached to a second front side panel 320 and a second rear side panel 322 of the rack 300. In certain embodiments, a rear mounting component 312 is attached between the first and second rear side panels 322. In certain embodiments, the first server mounting component 320 is attached via the mounting apertures 330. In certain embodiments, the second server mounting component is attached via the mounting apertures 330.

In certain embodiments, the rack has a plurality of dimensions. In certain embodiments, the plurality of dimensions includes a width dimension, a depth dimension, a height dimension, or a combination thereof. In certain embodiments, the width dimension is defined by a distance from the first front side panel 320 and the second front side panel 320. In certain embodiments, the depth dimension of the rack is defined by a distance from a front side panel 320 and a rear side panel 322. In certain embodiments, the height dimension is defined by a distance from a bottom of a side panel 320 to a top of the side panel 320.

In certain embodiments, a rack includes a plurality of vertically arranged mounting components. In certain embodiments, some or all of the vertically arranged mounting components are adapted to mount respective rack server type information handling systems to the rack. In certain embodiments, the server mounting components are configured to correspond to particular heights including rack unit heights and open unit heights.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the rack system 300 includes a power distribution system 350. In certain embodiments, the power distribution system 350 corresponds to power distribution system 160. In certain embodiments, the power distribution system 350 is configured to be installed to the server rack 300. In certain embodiments, the power distribution system 350 is configured to be installed on a rear portion of the server rack 300. In certain embodiments, the power distribution system 350 extends vertically across a rear portion of the server rack 300. In certain embodiments, the power distribution system 350 is attached to the top panel 324, the bottom panel 326, or a combination thereof. In certain embodiments, the power distribution system 350 includes a busbar 360 and an associated capacitance system 362. In certain embodiments, the capacitance system 352 extends vertically across a rear portion of the server rack 300. In certain embodiments, some or all of the rear mounting components 312 define power apertures 364. In certain embodiments, server type information handling systems 305 may be physically and electrically coupled to the busbar 360 through the power apertures 364.

In certain embodiments, the busbar distributed capacitance system is incorporated within the server rack by directly mounting a capacitance system to the busbar, by providing a capacitance system which includes a plurality of capacitive modules mounted to the busbar, by incorporating capacitive features into the busbar housing design (e.g., via conductive parallel plates separated by a dielectric material/filler), or a combination thereof.

Such a power distribution system advantageously adds a capacitance function to server racks which does not require additional system internal space or additional rack space. More specifically, associating a capacitance system with a busbar can avoid the need to accommodate additional components within an IT system chassis and can also avoid any slot penalty associated with adding a separate capacitive shelf.

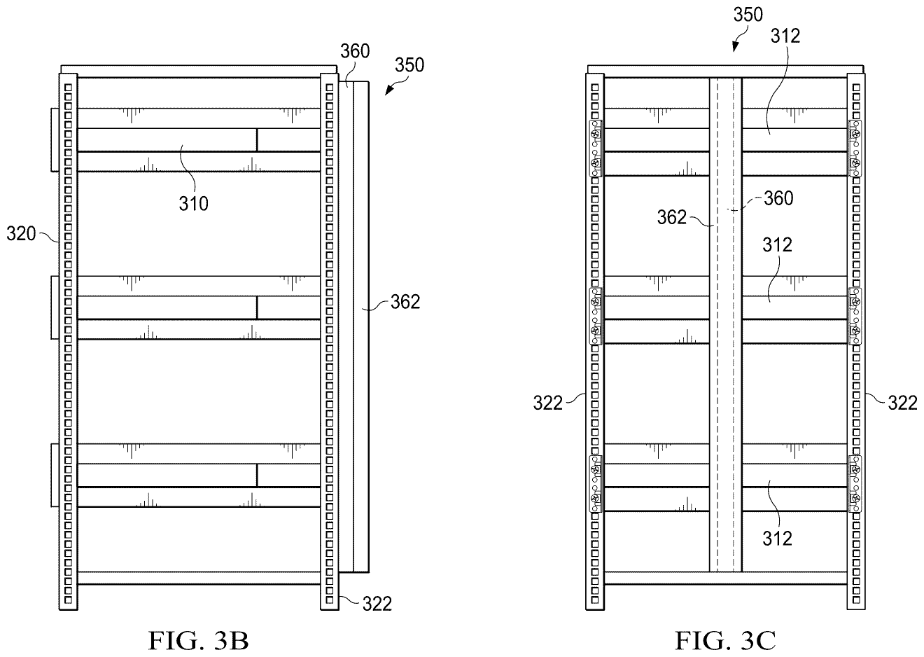

FIG. 4 shows a block diagram view of a server rack system 400 with a power distribution system 405 and a plurality of information handling systems 410. In certain embodiments, the server rack system 400 corresponds to server system 300. In certain embodiments, the power distribution system 405 corresponds to power distribution system 160. In certain embodiments, the information handling systems 410 include server type information handling systems 410a, power shelves 410b, or a combination thereof. In certain embodiments, power shelves 410b are located between at least pairs of server type information handling system 410a. In certain embodiments, at least pairs of server type information handling systems 410a are located above and below respective power shelves 410b.

In certain embodiments, the power distribution system 405 is configured to be installed to the server rack 400. In certain embodiments, the power distribution system 405 is configured to be installed on a rear portion of the server rack 400. In certain embodiments, the power distribution system 405 extends vertically across a rear portion of the server rack 400. In certain embodiments, the power distribution system 405 includes a power distribution device 420 and an associated capacitance system 422. In certain embodiments, the power distribution device 420 includes a busbar. In certain embodiments, the power distribution device 420 extends vertically across a rear portion of the server rack 400. In certain embodiments, the capacitance system 422 is physically and electrically coupled to the power distribution device 420. In certain embodiments, the capacitance system 422 extends vertically across a rear portion of the server rack 400. In certain embodiments, the capacitance system 422 is configured as a power distribution device distributed capacitance system. In certain embodiments, the power distribution device distributed capacitance system is configured as a busbar distributed capacitance system.

In certain embodiments, some or all of the information handling system 410 include power clips 430. In certain embodiments, the power clips 430 are configured to physically and electrically couple the information handling systems to the power distribution device 420. In certain embodiments, server type information handling systems 405 may be physically and electrically coupled to the power distribution device 420 through the power apertures 464.

In certain embodiments, the busbar distributed capacitance system is incorporated within the server rack by directly mounting a capacitance system to the busbar, by providing a capacitance system which includes a plurality of capacitive modules mounted to the busbar, by incorporating capacitive features into the busbar housing design (e.g., via conductive parallel plates separated by a dielectric material/filler), or a combination thereof.

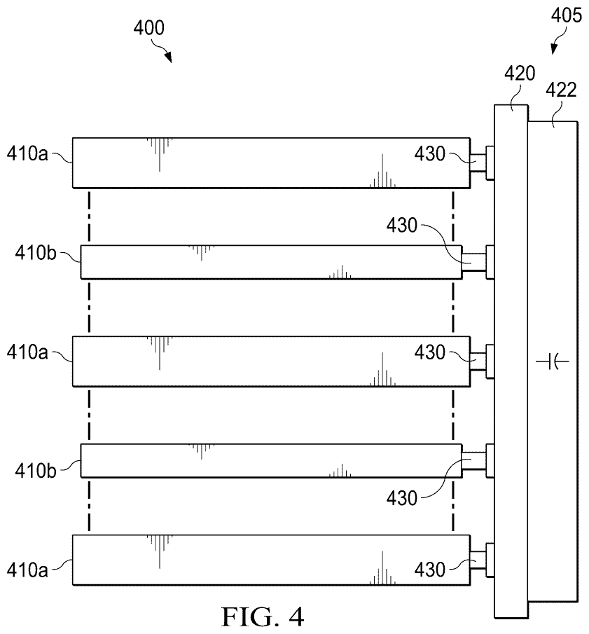

FIG. 5 shows a block diagram view of a server rack system 500 with another power distribution system 505 and a plurality of information handling systems 510. In certain embodiments, the server rack system 500 corresponds to server system 300. In certain embodiments, the power distribution system 505 corresponds to power distribution system 160. In certain embodiments, the power distribution system 505 includes a distributed capacitance system. In certain embodiments, the information handling systems 510 include server type information handling systems 510a, power shelves 510b, or a combination thereof. In certain embodiments, power shelves 510b are located between at least pairs of server type information handling system 510a. In certain embodiments, at least pairs of server type information handling systems 510a are located above and below respective power shelves 510b.

In certain embodiments, the power distribution system 505 is configured to be installed to the server rack 500. In certain embodiments, the power distribution system 505 is configured to be installed on a rear portion of the server rack 500. In certain embodiments, the power distribution system 505 extends vertically across a rear portion of the server rack 500.

In certain embodiments, the power distribution system 505 includes a busbar 520 and a plurality of associated capacitance components 522. In certain embodiments, the capacitance components 522 extend vertically across portions of a rear portion of the server rack 500. In certain embodiments, the capacitance components 522 extend vertically across portions a rear portion of the server rack 500 which include a pair of server type information handling systems 510a and a power shelf 510b located between the pair of server type information handling systems 510a.

In certain embodiments, some or all of the information handling system 510 include power clips 530. In certain embodiments, the power clips 530 are configured to physically and electrically couple the information handling systems to the busbar 520. In certain embodiments, server type information handling systems 505 may be physically and electrically coupled to the busbar 520 through the power apertures 564.

In certain embodiments, the busbar distributed capacitance components are incorporated within the server rack by directly mounting capacitance components to the busbar, by incorporating capacitive features into the busbar housing design (e.g., via conductive parallel plates separated by a dielectric material/filler), or a combination thereof.

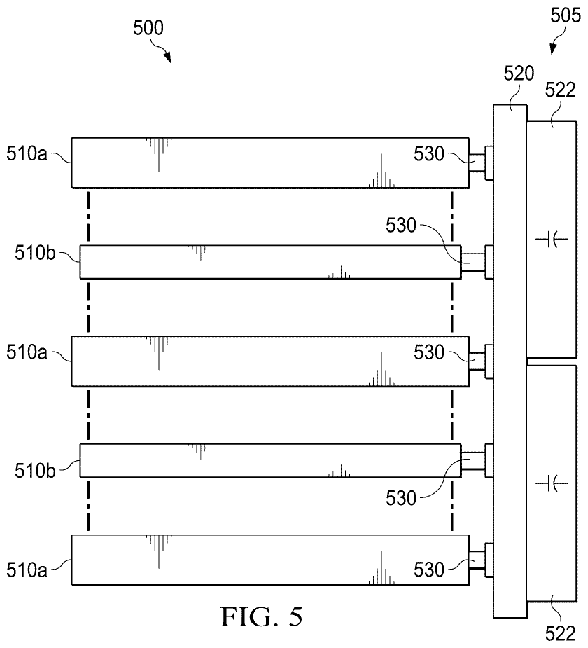

FIG. 6 shows a block diagram view of a server rack system 600 with another power distribution system 605 and a plurality of information handling systems 610. In certain embodiments, the server rack system 600 corresponds to server system 300. In certain embodiments, the power distribution system 605 corresponds to power distribution system 160. In certain embodiments, the power distribution system 605 includes a distributed capacitance system. In certain embodiments, the information handling systems 610 include server type information handling systems 610a, power shelves 610b, or a combination thereof. In certain embodiments, power shelves 610b are located between at least pairs of server type information handling system 610a. In certain embodiments, at least pairs of server type information handling systems 610a are located above and below respective power shelves 610b.

In certain embodiments, the power distribution system 605 is configured to be installed to the server rack 600. In certain embodiments, the power distribution system 605 is configured to be installed on a rear portion of the server rack 600. In certain embodiments, the power distribution system 605 extends vertically across a rear portion of the server rack 600.

In certain embodiments, the power distribution system 605 includes a busbar 620 and a plurality of associated capacitance components 622. In certain embodiments, the capacitance components 622 extend vertically across portions of a rear portion of the server rack 600. In certain embodiments, each capacitance components 622 extends vertically across portions a rear portion of the server rack 600 between a server type information handling systems 610a and an associated power shelf 610b.

In certain embodiments, some or all of the information handling system 610 include power clips 630. In certain embodiments, the power clips 630 are configured to physically and electrically couple the information handling systems to the busbar 620. In certain embodiments, server type information handling systems 605 may be physically and electrically coupled to the busbar 620 through the power apertures 664.

In certain embodiments, the busbar distributed capacitance components are incorporated within the server rack by directly mounting capacitance components to the busbar, by incorporating capacitive features into the busbar housing design (e.g., via conductive parallel plates separated by a dielectric material/filler), or a combination thereof.

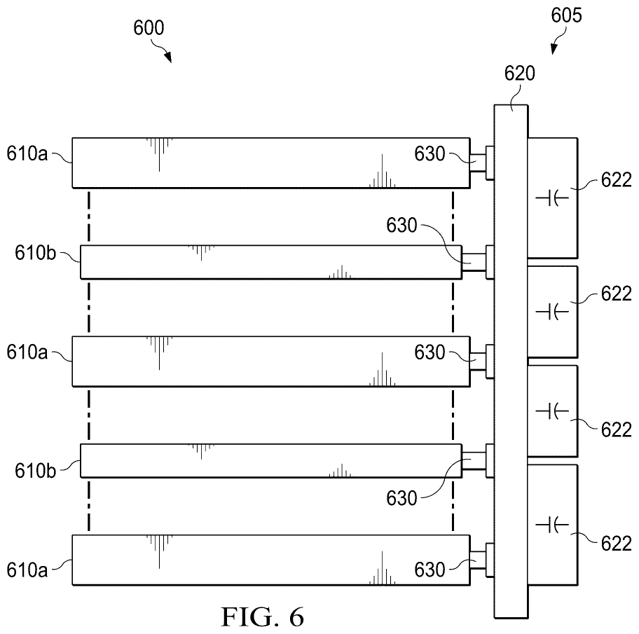

FIG. 7 shows a cross sectional view of a power distribution system 700. In certain embodiments, the power distribution system 700 corresponds to power distribution system 160. In certain embodiments, the power distribution system 700 includes a power distribution device 710, a distributed capacitance component 712, or a combination thereof. In certain embodiments, the power distribution device 710 includes a busbar component. In certain embodiments, the distributed capacitance component 712 includes a busbar distributed capacitance component. In certain embodiments, the distributed capacitance component 712 is directly mounted to the power distribution device 710.

In certain embodiments, the power distribution device 710 includes a connection portion 720, a power distribution portion 722, or a combination thereof, contained within a busbar housing 724. In certain embodiments, the connection portion 720 is configured to connect the power distribution system 700 with power connection clips of one or more information handling systems. In certain embodiments, the connection portion 720 includes a positive power contact 730, a negative power contact 732, or a combination thereof.

In certain embodiments, the power distribution portion 722 includes a positive power distribution element 740, a negative power distribution element 742, or a combination thereof. In certain embodiments, the positive power distribution element 730 and the negative power distribution element 732 are respectively electrically coupled to the positive power connection contact 730 and the negative power connection contact 732 of the connection portion 720.

In certain embodiments, distributed capacitance component 712 includes a capacitor element 750 contained within a capacitance component housing 752. In certain embodiments, the positive power distribution element 730 and the negative power distribution element 732 are respectively electrically coupled to a positive portion of the capacitor element 750 and a negative portion of the capacitor element 750.

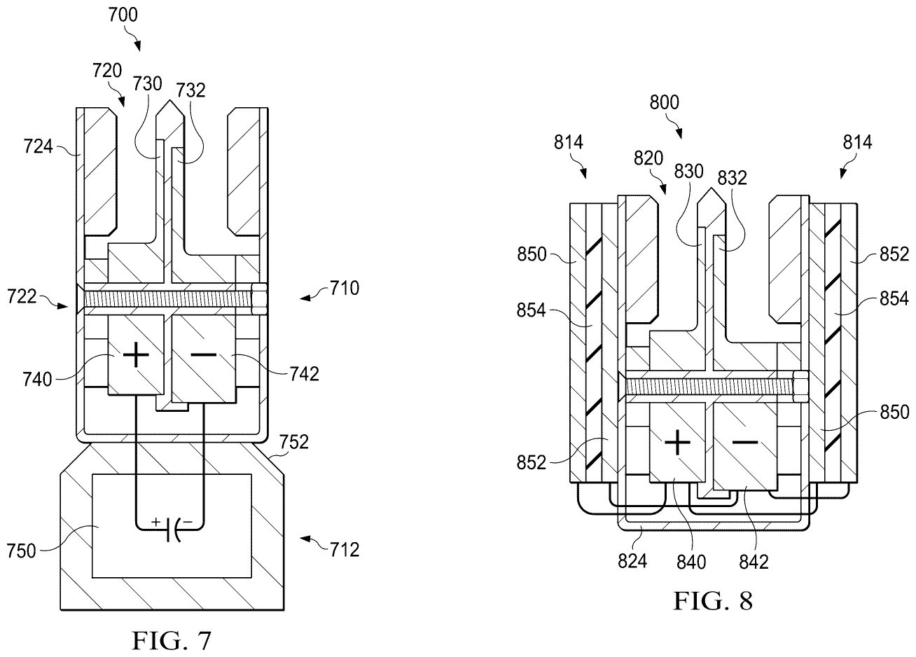

FIG. 8 shows a cross-sectional view of another power distribution system 800. In certain embodiments, the power distribution system 800 corresponds to power distribution system 160. In certain embodiments, the power distribution system 800 includes a power distribution device 810, one or a pair of distributed capacitance components 812, or a combination thereof. In certain embodiments, the power distribution device 810 includes a busbar component. In certain embodiments, the distributed capacitance components 812 include busbar distributed capacitance components. In certain embodiments, the distributed capacitance components 812 are directly mounted to respective sides of the power distribution device 810.

In certain embodiments, the power distribution device 810 includes a connection portion 820, a power distribution portion 822, or a combination thereof, contained within a busbar housing 824. In certain embodiments, the connection portion 820 is configured to connect the power distribution system 800 with power connection clips of one or more information handling systems. In certain embodiments, the connection portion 820 includes a positive power contact 830, a negative power contact 832, or a combination thereof.

In certain embodiments, the power distribution portion 822 includes a positive power distribution element 840, a negative power distribution element 842, or a combination thereof. In certain embodiments, the positive power distribution element 830 and the negative power distribution element 832 are respectively electrically coupled to the positive power connection contact 830 and the negative power connection contact 832 of the connection portion 820.

In certain embodiments, each distributed capacitance component 812 includes a positive capacitor element 850, a negative capacitor element 852, or a combination thereof. In certain embodiments, the busbar distributed capacitance system is incorporated within the server rack by directly mounting a capacitance system to the busbar by incorporating the positive capacitor element 850 and the negative capacitor element 852 into the busbar housing design. In certain embodiments, the positive capacitor element 850 and the negative capacitor element 852 each include conductive parallel plates separated by a dielectric material/filler 854. In certain embodiments, the positive power distribution element 830 and the negative power distribution element 832 are respectively electrically coupled to a positive portion of the capacitor element 850 and a negative portion of the capacitor element 850.

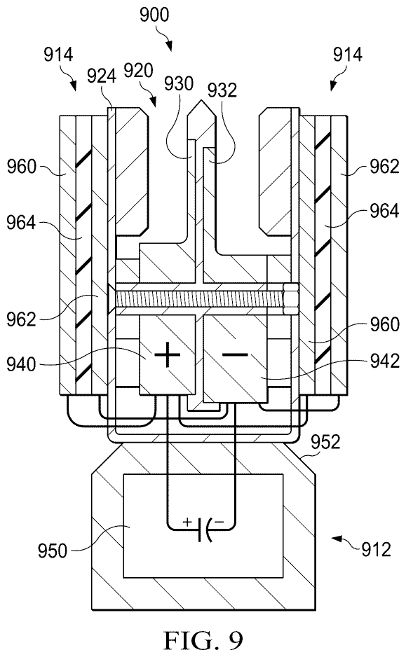

FIG. 9 shows a cross-sectional view of another power distribution system 900. In certain embodiments, the power distribution system 900 corresponds to power distribution system 160. In certain embodiments, the power distribution system 900 corresponds to power distribution system 160. In certain embodiments, the power distribution system 900 includes a power distribution device 910, a distributed capacitance component 912, one or a pair of distributed capacitance components 914, or a combination thereof. In certain embodiments, the power distribution device 910 includes a busbar component. In certain embodiments, the distributed capacitance component 712 is directly mounted to a rear side of the power distribution device 710. In certain embodiments, the distributed capacitance components 912 are directly mounted to respective sides of the busbar component 910.

In certain embodiments, the power distribution device 910 includes a connection portion 920, a power distribution portion 922, or a combination thereof, contained within a busbar housing 924. In certain embodiments, the connection portion 920 is configured to connect the power distribution system 900 with power connection clips of one or more information handling systems. In certain embodiments, the connection portion 920 includes a positive power contact 930, a negative power contact 932, or a combination thereof.

In certain embodiments, the power distribution portion 922 includes a positive power distribution element 940, a negative power distribution element 942, or a combination thereof. In certain embodiments, the positive power distribution element 930 and the negative power distribution element 932 are respectively electrically coupled to the positive power connection contact 930 and the negative power connection contact 932 of the connection portion 920.

In certain embodiments, the distributed capacitance component 712 includes a capacitor element 750 contained within a capacitance component housing 752. In certain embodiments, the positive power distribution element 730 and the negative power distribution element 732 are respectively electrically coupled to a positive portion of the capacitor element 750 and a negative portion of the capacitor element 750.

In certain embodiments, the distributed capacitance components 914 includes a positive capacitor element 960, a negative capacitor element 962, or a combination thereof. In certain embodiments, the busbar distributed capacitance system 914 is incorporated within the server rack by directly mounting a capacitance system to the busbar by incorporating the positive capacitor element 960 and the negative capacitor element 962 into the busbar housing design. In certain embodiments, the positive capacitor element 960 and the negative capacitor element 962 each include conductive parallel plates separated by a dielectric material/filler. In certain embodiments, the positive power distribution element 930 and the negative power distribution element 932 are respectively electrically coupled to a positive portion of the capacitor element 960 and a negative portion of the capacitor element 960.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A power distribution system for an information handling system server rack, comprising:
a power distribution device, the power distribution device extending across the information handling system server rack; and,
a capacitance system associated with the power distribution device, the capacitance system being physically and electrically coupled to the power distribution device.

2. The power distribution system of claim 1, wherein:
the power distribution system extends across a plurality of information handling systems mounted in the information handling system server rack; and,
the capacitance system extends across a plurality of information handling systems mounted in the information handling system server rack.

3. The power distribution system of claim 2, wherein:
the plurality of information handling systems include at least one server type information handling system and at least one power shelf; and,
the capacitance system extends between the at least one server type information handling system and the at least one power shelf.

4. The power distribution system of claim 3, wherein:
the plurality of information handling systems include a second server type information handling system; and,
the capacitance system extends between the at least one server type information handling system the at least one power shelf and the second server type information handling system.

5. The power distribution system of claim 1, wherein:
the capacitance system includes at least one of a power distribution system capacitance component directly mounted to a rear of the power distribution device and a power distribution system capacitance component mounted to a side of the power distribution device.

6. The power distribution system of claim 5, wherein:
the capacitance system includes both of the power distribution system capacitance component directly mounted to a rear of the power distribution device and the power distribution system capacitance component mounted to a side of the power distribution device.

7. An information handling system server rack comprising:
a server rack panel; and,
a power distribution system mounted to the server rack panel, the power distribution system comprising
a power distribution device, the power distribution device extending across the information handling system server rack; and,
a capacitance system associated with the power distribution device, the capacitance system being physically and electrically coupled to the power distribution device.

8. The information handling system server rack of claim 7, wherein comprises:
the power distribution system extends across a plurality of information handling systems mounted in the information handling system server rack; and,
the capacitance system extends across a plurality of information handling systems mounted in the information handling system server rack.

9. The information handling system server rack of claim 8, wherein:
the plurality of information handling systems include at least one server type information handling system and at least one power shelf; and,
the capacitance system extends between the at least one server type information handling system and the at least one power shelf.

10. The information handling system server rack of claim 9, wherein:
the plurality of information handling systems include a second server type information handling system; and,
the capacitance system extends between the at least one server type information handling system the at least one power shelf and the second server type information handling system.

11. The information handling system server rack of claim 7, wherein:
the capacitance system includes at least one of a power distribution system capacitance component directly mounted to a rear of the power distribution device and a power distribution system capacitance component mounted to a side of the power distribution device.

12. The information handling system server rack of claim 11, wherein:
the capacitance system includes both of the power distribution system capacitance component directly mounted to a rear of the power distribution device and the power distribution system capacitance component mounted to a side of the power distribution device.
